(19) United States
(12) Patent Application Publication
(10) Pub. No.: US 2026/0068621 A1
(43) Pub. Date: Mar. 5, 2026

(54) CONDUCTIVE VIAS FOR THREE DIMENSIONAL INTEGRATION

(71) Applicant: Intel Corporation, Santa Clara, CA (US)

(72) Inventors: Sagar Suthram, Portland, OR (US); Doug B. Ingerly, Portland, OR (US); Wilfred Gomes, Portland, OR (US); Pushkar Sharad Ranade, San Jose, CA (US); Abhishek A. Sharma, Portland, OR (US)

(73) Assignee: Intel Corporation, Santa Clara, CA (US)

(21) Appl. No.: 18/818,970

(22) Filed: Aug. 29, 2024

(51) Int. Cl. H01L 23/48; H01L 23/00; H01L 25/065

(52) U.S. Cl. CPC H01L 23/481

(57) ABSTRACT

Conductive vias for 3D integration may be formed during or after assembly to couple dies or die stacks. In one example, such conductive vias may extend through the dies or die stacks and through an interface with conductive bumps, without terminating on the bumps. Bypassing conductive bumps with a conductive via may enable improved performance, power delivery, and thermal management. In one example, an assembly includes a first IC structure (such as a substrate, interposer, or other IC structure) and a second IC structure (such as a die or die stack) over the first IC structure. The assembly includes an interface layer between the first IC structure and the second IC structure, where the interface layer includes a plurality of conductive bumps. A conductive via extends through the interface layer with the bumps and is coupled with a conductive element of the first IC structure.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize fabrication and performance of each component is becoming increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is a cross-sectional diagram of a microelectronic assembly including conductive vias for 3D integration, in accordance with some embodiments.

FIG. 1B is a diagram of a die that may be included in an assembly that includes conductive vias for 3D integration, in accordance with embodiments.

FIG. 1C is a cross-sectional diagram of an assembly including conductive vias for 3D integration, in accordance with some embodiments.

FIG. 1D is a cross-sectional diagram of an assembly including conductive vias for 3D integration, in accordance with some embodiments.

FIG. 2 illustrates a cross-sectional view of a microelectronic assembly with conductive vias for 3D integration, in accordance with some embodiments.

FIGS. 3A-3G illustrate cross-sectional views of examples of assemblies in which conductive vias for 3D integration may be formed.

FIG. 4 is a flow diagram of an example method for fabricating a microelectronic assembly with conductive vias for 3D integration, in accordance with some embodiments.

FIGS. 5A-5D provide cross-sectional side views at various stages in the fabrication of an example IC structure according to the method of FIG. 4, in accordance with some embodiments.

FIG. 6 is a top view of a wafer and dies that may include any of the IC devices disclosed herein, in accordance with any of the embodiments disclosed herein.

FIG. 7 is a side, cross-sectional view of an IC package that may include any of the IC devices disclosed herein, in accordance with various embodiments.

FIG. 8 is a side, cross-sectional view of an IC device assembly that may include any of the IC devices disclosed herein, in accordance with any of the embodiments disclosed herein.

FIG. 9 is a block diagram of an example electrical device that may include any of the IC devices disclosed herein, in accordance with any of the embodiments disclosed herein.

### DETAILED DESCRIPTION

Disclosed herein are microelectronic assemblies and integrated circuit (IC) structures including conductive vias for three dimensional (3D) integration. The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

Semiconductor chip manufacturing involves a series of complex processes to create IC structures. These processes include photolithography, ion implantation, etching, and deposition. A wafer typically goes through multiple rounds of these processes to form devices and interconnects on the wafer. Once the wafer processing is complete, the wafer may be cut into individual chips (also called dies). After dicing, the individual dies are packaged to provide interconnections with other components and protection.

Packaging the dies may involve attaching the dies to a substrate (such as a motherboard, interposer, or other circuit board or structure with conductive interconnects) to connect the die's conductive contacts to the package's conductive contacts (e.g., with flip-chip bonding, ball grid array (BGA), etc.). For attachment to a circuit board, a die may be soldered directly onto the board or inserted into a socket (e.g., in the case of a packaged die). In some cases, multiple dies may be combined (e.g., stacked) into a single assembly or package before being mounted on the circuit board.

Two dies or die stacks on a circuit board may communicate with one another through conductive interconnects in the circuit board and through pads and bumps at the interface between the circuit board and the dies or die stacks. Thus, conductive lines and vias in each of the dies or die stacks typically end on the bumps at the interface between the circuit board and the dies. The bumps at the interface between the dies and the circuit board can be a limiting factor with regards to performance, power delivery, and thermal management. For example, solder bumps may prevent high frequency signaling at the interface with the bumps (e.g., due to signal distortion and crosstalk). Solder bumps may also limit power delivery through an interface with solder bumps due to the limited current carrying capacity of solder bumps and the risk of electromigration in solder bumps at high current densities. Solder bumps at the interface may also pose challenges for thermal management (e.g., due to limitations in the thermal conductivity of solder bumps).

According to examples described herein, conductive vias for 3D integration may be formed during or after assembly to couple dies or die stacks with one another. In one example, such conductive vias may extend through the dies or die stacks and through an interface with conductive bumps, without terminating on the bumps. Bypassing conductive bumps with a conductive via may enable improved performance, power delivery, and thermal management. In one example, an assembly includes a first IC structure (such as a substrate, interposer, or other IC structure) and a second IC structure (such as a die or die stack) over the first IC structure. The assembly includes an interface layer between the first IC structure and the second IC structure, where the interface layer includes a plurality of conductive bumps (e.g., in contact with the first IC structure and the second IC structure, and coupled with conductive elements in the first and second IC structures) and an insulator material in a plane with the conductive bumps. A conductive via extends through the interface layer with the bumps and is coupled with a conductive element of the first IC structure.

IC structures as described herein, in particular IC structures including conductive vias for 3D integration, may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC (RFIC), which may, e.g., be included in any component associated with an IC of an RF receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials, and configurations are set forth in order to provide a thorough understanding of the illustrative implementations. However, it will be apparent to one skilled in the art that the present disclosure may be practiced without the specific details and/or that the present disclosure may be practiced with only some of the described aspects. In other instances, well-known features are omitted or simplified in order not to obscure the illustrative implementations. The terms “substantially,” “close,” “approximately,” “near,” and “about,” generally refer to being within +/−10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC structures and assemblies including conductive vias for 3D integration as described herein.

Various aspects of the illustrative implementations will be described using terms commonly employed by those skilled in the art to convey the substance of their work to others skilled in the art. For example, the terms “oxide,” “carbide,” “nitride,” “silicide,” etc. refer to compounds containing, respectively, oxygen, carbon, nitrogen, silicon, etc.; the term “high-k dielectric” refers to a material having a higher dielectric constant than silicon oxide; the term “low-k dielectric” refers to a material having a lower dielectric constant than silicon oxide. Materials referred to herein with formulas or as compounds cover all materials that include elements of the formula or a compound, e.g., TiSi or titanium silicide may refer to any material that includes titanium and silicon, WN or tungsten nitride may refer to any material that includes tungsten and nitrogen, etc. The term “insulating” means “electrically insulating,” the term “conducting” means “electrically conducting,” unless otherwise specified. Furthermore, the term “connected” may be used to describe a direct electrical or magnetic connection between the things that are connected, without any intermediary devices, while the term “coupled” may be used to describe either a direct electrical or magnetic connection between the things that are connected, or an indirect connection through one or more passive or active intermediary devices. A first component described to be electrically coupled to a second component means that the first component is in conductive contact with the second component (i.e., that a conductive pathway is provided to route electrical signals/power between the first and second components).

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

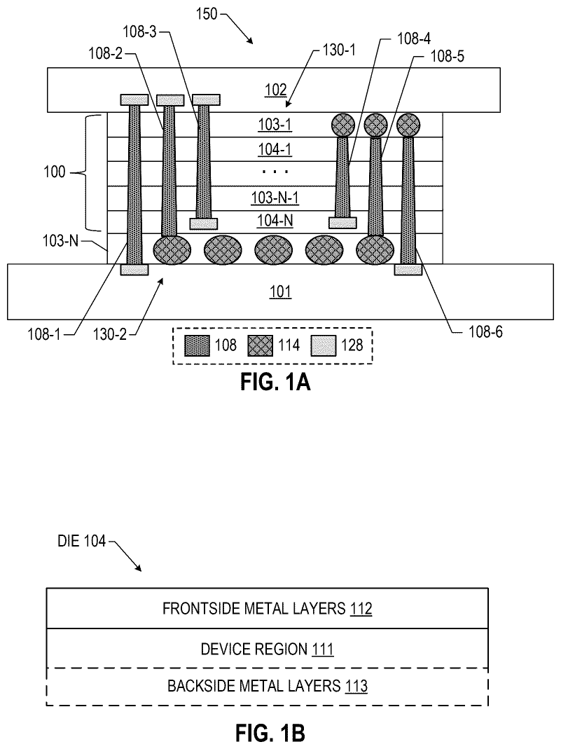

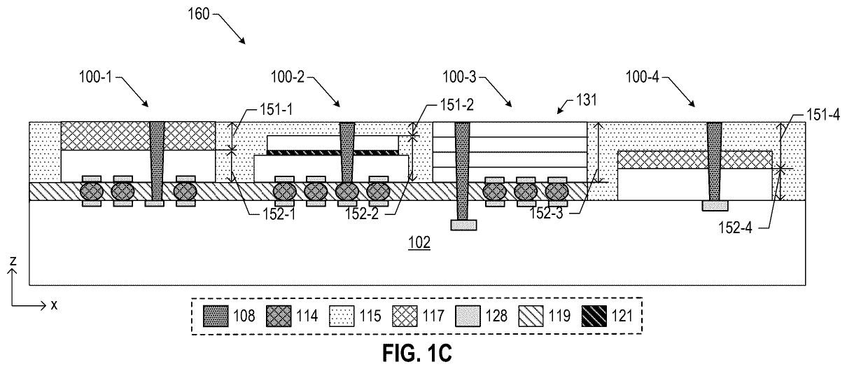

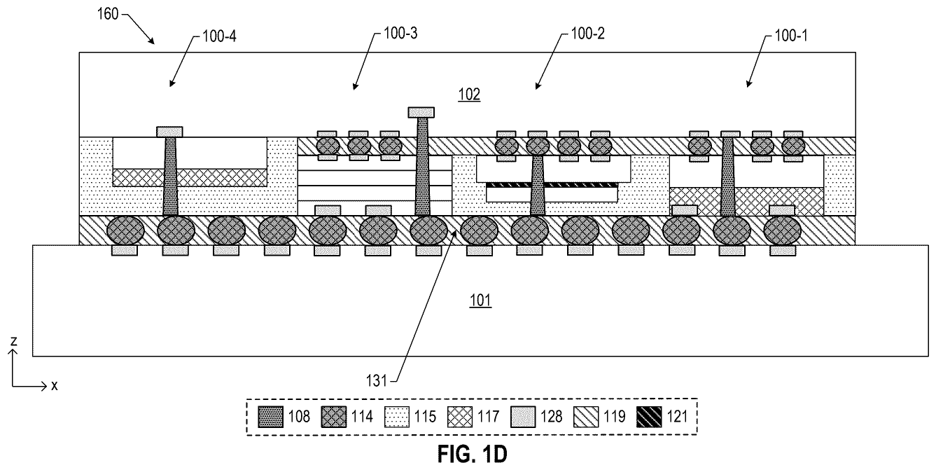

FIG. 1A is a cross-sectional diagram of a microelectronic assembly 150 including conductive vias for 3D integration. The assembly 150 includes an IC structure 100 bonded with a substrate 102 and a circuit board 101. The IC structure shown in FIG. 1A includes a plurality of N dies 104-1-104-N (of which dies 104-1 and 104-N are shown) stacked over and bonded with one another, where N is a positive integer greater than or equal to two. A plurality of dies stacked over one another may be referred to as a die stack. In some examples, the number of dies 104-1-104-N in a die stack may be, e.g., two, three, four, eight, or some other positive integer greater than or equal to two. In practice, the number of dies 104-1-104-N stacked over one another in a die stack may be limited by a variety of factors, including challenges related to thermal management and connectivity. Although a stack of multiple dies 104-1-104-N is shown in FIG. 1A, in some examples, one or more IC structures including conductive vias for 3D integration may include a single die (e.g., a single active die including logic and/or memory devices). The dies 104-1-104-N may be the same type of die, or may include different types of dies. For example, one or more of the dies 104-1-104-N may include compute logic (e.g., a processor die, an accelerator die, or other die with compute logic), a memory die, a die with both compute logic and memory, or another type of die.

Each one of the dies 104-1-104-N may include a device region and conductive interconnect layers. For example, FIG. 1B shows a diagram of a die 104 with a device region 111, frontside metal layers 112 over the device region, and backside metal layers 113. The device region includes devices formed over a substrate, and may include or be referred to as a front end of line (FEOL) layer. The device region 111 may include frontend devices (e.g., frontend transistors such as FinFETs, nanowire/nanoribbon transistors, frontend memory cells, or other frontend devices). The frontside metal layers 112 are over a front side of the device region, and the backside metal layers 113 are over a back side of the device region. The metal layers 112, 113 may also be referred to as back end of line (BEOL) layers. Various metal layers 112, 113 may be used to interconnect the various inputs and outputs of the devices (e.g., logic devices or memory devices) in the device regions 111. In one example, each of the metal layers may include vias and lines/trenches, as discussed in further detail below. The metal layers 112, 113 may also include devices (e.g., backend devices). Some dies may include more, fewer, and or different layers/regions than shown in FIG. 1B. For example, some dies may have only a device region and frontside metal layers 112, but lack backside metal layers. Other dies may lack a device region (e.g., an interconnect die).

Referring again to FIG. 1A, the IC structure 100 may include interfaces 103-1-103-N-1 between adjacent dies of the IC structure 100 (e.g., between vertically adjacent stacked dies). The assembly 150 further includes an interface 103-N between the IC structure 100 and the circuit board 101. The interfaces 103-1-103-N may include any suitable interface (e.g., a hybrid bonding interface, an interface including conductive bumps such as BGA, or other interface). The example in FIG. 1A depicts the interface 103-1 between the substrate 102 and the die 104-1 as including conductive bumps 114, and the interface 103-N between the die 104-N and the circuit board 101 as including conductive bumps 114. Also as illustrated in the example of FIG. 1A, the interface 103-N between the circuit board 101 and the IC structure 100 may have conductive bumps 114 with a larger pitch than an interface between dies of a die stack (e.g., the conductive bumps 114 of the interface 103-1).

The substrate 102 may include a structure that includes conductive interconnects, a structure that provides mechanical stability and support, or a structure that provides both conductive interconnects and mechanical support. The substrate 102 may also be referred to as a package substrate. In one example, the substrate 102 may be an interposer, interconnect die or structure, or other IC structure including conductive interconnects that coupled with conductive interconnects in one or more of the dies 104-1-104-N. Conductive interconnects in the substrate 102 may include conductive traces (e.g., lines) and vias. In one such example, the substrate 102 includes primarily conductive interconnect without compute logic (e.g., compute logic may be absent from the substrate 102). In other examples, the substrate 102 may be primarily or entirely a support structure without conductive interconnects coupled with the dies 104-1-104-N. In one example, the substrate 102 includes an insulating material (e.g., a dielectric material formed in multiple layers, as known in the art). In some embodiments, the insulating material of the substrate 102 may be a dielectric material, such as an organic dielectric material, a fire retardant grade 4 material (FR-4), bismaleimide triazine (BT) resin, polyimide materials, glass reinforced epoxy matrix materials, or low-k and ultra-low-k dielectric (e.g., carbon-doped dielectrics, fluorine-doped dielectrics, porous dielectrics, and organic polymeric dielectrics).

The circuit board 101 may be a printed circuit board (PCB), such as a motherboard, and may have other IC structures and/or components attached to it (not shown in FIG. 1A). The circuit board 101 may include conductive pathways and other conductive contacts (not shown) for routing power, ground, and signals through the circuit board 101 to the IC structure 100 and other IC structures attached to the circuit board 101, as known in the art.

The assembly 150 also includes a plurality of conductive vias 108 extending through one or more dies of the IC structure 100. The conductive vias 108 may be used for transmitting data signals, power, ground, or for providing thermal channels. In some examples, the conductive vias 108 include one or more of copper, tungsten, titanium nitride, ruthenium, molybdenum, tungsten nitride, copper aluminum, or any other suitable conductive material. In the example illustrated in FIG. 1A, each of the conductive vias is coupled with conductive elements, such as a conductive pad 128 (which may be referred to as a bond pad, contact pad, or landing pad), a conductive bump 114, or other conductive contact. The conductive pads 128 include a conductive material, such as one or more of copper, silver, gold, molybdenum, alloys thereof, and/or other metals. The plurality of conductive vias 108 may be formed after attaching the IC structure 100 to the substrate 102 and before attaching the IC structure 100 to the circuit board 101. A first face 130-1 of the IC structure 100 may be bonded to the substrate 102 with any suitable technique, such as hybrid bonding or with a plurality of conductive bumps. The plurality of conductive vias 108 may then be formed from a second face 130-2 of the IC structure 100 (and/or from the interface 103-N). The IC structure 100 may then be flipped over and attached to the circuit board 101, such that the second face 130-2 of the IC structure 100 is attached to the circuit board 101 and the first face 130-1 of the IC structure 100 is attached to the substrate 102. Thus, the plurality of conductive vias 108 shown in FIG. 1A start at or proximate to the interface 103-N with the circuit board 101 (e.g., in the interface 103-N or in a metal layer of a die closest to the circuit board 101) and end at, in, or proximate to the substrate 102. Therefore, the plurality of conductive vias 108 of FIG. 1A taper in a direction from the circuit board 101 towards the substrate 102.

Unlike in conventional assemblies, in some examples, at least one of the conductive vias passes through an interface with conductive bumps. For example, the conductive via 108-1 extends through the interface 103-N with conductive bumps 114, through all the dies of the IC structure 100, through the interface 103-1 with conductive bumps 114, and into the substrate 102. Similarly, the conductive via 108-2 extends through all the dies of the IC structure 100, through the interface 103-1 with conductive bumps 114, and into the substrate 102. The conductive via 108-3 starts at a metal layer in the die 104-N, extends partially through the die 104-N, extends through the other dies of the stack, extends through the interface 103-1 with conductive bumps 114, and ends in the substrate 102. The conductive vias 108-4, 108-5, 108-6 show examples of vias that end at the interface 103-1 (e.g., at the conductive bumps 114 of the interface 103-1 rather than extending through the interface 103-1).

Thus, conductive vias 108 may be formed during assembly to enable the formation of vias that extend through inter-die interfaces rather than vias that terminate at conductive bumps. Conductive vias in accordance with examples described herein may enable improved system performance (e.g., by enabling high frequency signaling between adjacent IC structures on a circuit board). Conductive vias in accordance with examples described herein may also enable improved thermal management. Unlike conventional IC structures in which conductive vias terminate at interfaces with conductive bumps, resulting in thermal boundaries that limit heat dissipation, conductive vias for 3D integration can enable a thermal channel between multiple dies without thermal boundaries for improved thermal management. Finally, conductive vias formed during or after assembly of various components can enable flexibility in terms of multi-fabrication processing. For example, conductive vias may be formed at different stages of fabrication and assembly to enable the use of packages and dies from multiple fabs.

For example, FIG. 1C illustrates an example of an assembly 160 including a substrate 102 with a plurality of different IC structures 100-1, 100-2, 100-3, and 100-4 over the substrate 102. The assembly 160 may be a preliminary assembly that is to be bonded with a circuit board (e.g., the circuit board 101, as shown in FIG. 1A). For example, the preliminary assembly 160 may be flipped over and the side 131 opposite the substrate 102 may be bonded with a circuit board 101. The different IC structure 100-1-100-4 are coplanar (e.g., at least some portion of each of the IC structures 100-1-100-4 is in the same plane parallel with the substrate 102) and bonded with the substrate 102. The IC structures 100-1-100-4 may be bonded with the substrate 102 in accordance to any suitable bonding technique.

As shown in FIG. 1C, the IC structures 100-1, 100-2, and 100-3 are bonded with the substrate 102 with conductive bumps 114. An interface with conductive bumps may include a plurality of coplanar bumps between the two bonded IC structures (e.g., between two dies). The conductive bumps 114 are typically coupled with conductive elements, such as conductive pads 128. For example, in FIG. 1C, each of the conductive bumps 114 is between two conductive pads, or a conductive pad and a conductive via 108. In some examples, the bumps may be arranged in an array, such as in ball grid array (BGA) assemblies. Conductive bumps may be formed to have various shapes (e.g., spherical/round, cylindrical, etc.), which may be deformed after bonding. Conductive bumps include a conductive material (e.g., one or more metals), such as solder, copper, gold, or other suitable conductive material. Conductive bumps that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, a set of conductive bumps may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression.

In some examples, the conductive bumps 114 are surrounded by an insulator material 119 (sometimes referred to as a filler or underfill material) in a plane with the conductive bumps. The insulator material 119 may be provided according to any suitable method (e.g., deposited before or after formation of the bumps), and may provide mechanical support to an interface layer with conductive bumps 114. The insulator material 119 may be any suitable insulator material, such as silicon oxide, silicon carbide, silicon oxynitride, carbon-doped silicon oxide, spin-on-glass, boron-doped silicon oxide, an organic polymer, carbon, a carbon polymer, or any other suitable insulator material.

Another technique for bonding two IC structures, such as two dies, is hybrid bonding. For example, the IC structure 100-4 is hybrid bonded (e.g., without intervening conductive bumps) with the substrate 102. In hybrid bonding, the bonding process is between a first layer of a first IC structure and a second layer of a second IC structure and also between conductive structures within the first layer and conductive structures within the second layer. For example, in hybrid bonding, a conductive structure (e.g., a via including metal) extends through each of the first and second layers, prior to these layers being bonded to form the bonding interface layer. For example, a first interconnect structure extends through the first layer and is exposed through, and flush with, a surface of the first layer; and a second interconnect structure extends through the second layer and is exposed through, and flush with, a surface of the second layer (e.g., prior to the bonding process). During the bonding process, surfaces of the first layer and the second layers bond to form a bonding interface layer, along with a bonding or contact of the first interconnect structure and the second interconnect structure. The interconnect structures in adjacent stacked dies that are bonded together may be, for example, conductive vias, conductive pads, or any other suitable conductive elements that may be bonded together via a hybrid bonding process. For example, the conductive via 108 through the IC structure 100-4 is bonded with the pad 128 at the interface of the IC structure 100-4 and the substrate 102. In one example, due to unintentional practical considerations of the bonding process, the conductive interconnects of the first and second layers may not be perfectly aligned during the bonding process. Accordingly, sections of a combined interconnect structures formed through a hybrid bonding process, which extend through the bonding interface layer, may have some misalignment or offset.

Hybrid bonding may involve bonding a front side of one die to a back side of another die (e.g., “front-to-back”), bonding the back side of one die to the back side of another die (e.g., “back-to-back”), or bonding the front side of one die to the front side of another die (e.g., “front-to-front”). The side of a substrate on which a device layer is provided is typically referred to as a front side, and the other side of the substrate is referred to as a back side.

In some embodiments, hybrid bonding may be performed using insulator-insulator bonding, e.g., as oxide-oxide bonding, where an insulator material of one die is bonded with the insulator material of another die. In some embodiments, a bonding material may be present in between the faces that are bonded together. To that end, the bonding material may be applied to the one or both faces that are to be bonded and then the faces are put together, possibly while applying a suitable pressure and heating up the assembly to a suitable temperature (e.g., to moderately high temperatures, e.g., between about 50 and 200 degrees Celsius) for a duration of time. In some embodiments, the bonding material may be an adhesive material that ensures attachment of the faces of different IC structures to one another. In some embodiments, the bonding material may be an etch-stop material. In some embodiments, the bonding material may be both an etch-stop material and have suitable adhesive properties to ensure attachment of the first and second IC structures to one another. In some embodiments, the bonding material may include silicon, nitrogen, and carbon, where the atomic percentage of any of these materials may be at least 1%, e.g., between about 1% and 50%, indicating that these elements are added deliberately, as opposed to being accidental impurities which are typically in concentration below about 0.1%. Having both nitrogen and carbon in these concentrations in addition to silicon is not typically used in conventional semiconductor manufacturing processes where, typically, either nitrogen or carbon is used in combination with silicon, and, therefore, could be a characteristic feature of the hybrid bonding. Using, at a bonding interface, an etch-stop material that includes include silicon, nitrogen, and carbon, where the atomic percentage of any of these materials may be at least 1%, e.g., SiOCN, may be advantageous in terms that such a material may act both as an etch-stop material, and have sufficient adhesive properties to bond.

In some embodiments, no bonding material may be used, but there will still be a bonding interface resulting from the hybrid bonding. Such a bonding interface may be recognizable as a seam or a thin layer in the microelectronic assembly, using, e.g., selective area diffraction (SED), even when the specific materials of the insulators of the layers that are bonded together may be the same, in which case the bonding interface would still be noticeable as a seam or a thin layer in what otherwise appears as a bulk insulator (e.g., bulk oxide) layer.

In some examples, one or more of the IC structures 100-1-100-4 may include an interconnect die between adjacent stacked dies of the IC structure, and/or between the IC structure and the substrate 102. For example, the IC structure 100-2 includes an interconnect die 121 between two stacked dies. An interconnect die includes primarily, or exclusively, conductive interconnects, and may be thinner than a die with both a device region and interconnect layers. In some examples, an interconnect die may lack devices such as transistors. In other examples, the interconnect die may have some devices (e.g., switches) for signal routing purposes, but lack compute logic devices. In one example, an interconnect die may be hybrid bonded with dies on either side of the interconnect die.

Various IC structures 100-1-100-4 may include different numbers of dies (e.g., the IC structures 100-1-100-4 may include one die or multiple stacked dies) and/or different types of dies (e.g., some of the IC structures 100-1-100-4 may include only memory dies, only logic dies, dies with both logic and memory, or a combination of types of dies). The various IC structures 100-1-100-4 may also have different heights or thicknesses relative to one another after bonding to the substrate 102. For example, the IC structure 100-1 has a height 152-1, the IC structure 100-2 has a height 152-2, the IC structure 100-3 has a height 152-3, and the IC structure 100-4 has a height 152-4 (where the heights of the IC structures are dimensions of the IC structures in a plane substantially orthogonal to the substrate 102, e.g., along the z-axis as shown in FIG. 1C). The heights of the IC structures may also be referred to as thicknesses of the IC structures.

As can be seen in FIG. 1C, the height 152-3 is greater than the heights 152-1, 152-2, and 152-4. Put another way, the height or thickness of some of the IC structures is smaller than the heights or thicknesses of other IC structures. For example, the height 152-1 and the height 152-4 are smaller than the heights 152-2 and 152-3 and the height 152-2 is smaller than the height 152-3. Thus, there is a height or thickness difference between the IC structures 100-1, 100-2, and 100-4 and the IC structure 100-3. Specifically, there is a thickness difference 151-1 between the IC structures 100-1 and 100-3, a thickness difference 151-2 between the IC structures 100-2 and 100-3, and a thickness difference 151-4 between the IC structures 100-4 and 100-3. In some examples, an insulator material 115 may be provided over and between the IC structures 100-1-100-4 to form a substantially flat or level surface over the plurality of IC structures 100-1-100-4. The IC structure 100-2 is an example of where an insulator material 115 is over the IC structure 100-2 in a plane with a taller IC structure (e.g., the insulator material 115 over the IC structure 100-2 is coplanar with the top layer or face of the IC structure 100-3). The insulator material 115 may be the same as, or different from, the insulator material 119 in the interface layer with the conductive bumps 114. In other examples, a dummy die 117 may be provided over one or more of the shorter IC structures to increase the height or thickness of the structure. The IC structure 100-1 is an example where a dummy die 117 is bonded over the IC structure 100-1, where the dummy die is in a plane with the taller IC structure 100-3 (e.g., the dummy die 117 is coplanar with the top layer or face of the IC structure 100-3). A dummy die may be a die that lacks devices (e.g., active devices). In other examples, both a dummy die (or multiple dummy dies) and an insulator material 115 may be used to level the height or thickness of different IC structures 100-1-100-4 over the substrate 102. The IC structure 100-4 is an example where both a dummy die 115 and the insulator material 115 is used to account for the height differences between IC structures over the substrate 102.

Conductive vias 108 are formed through various IC structures of the assembly 160. As can be seen in FIG. 1C, the plurality of conductive vias 108 are formed from the side 131 of the assembly 160 opposite the substrate 102, and thus taper towards the substrate 102. Various ones of the conductive vias 108 land or terminate on conductive elements in the substrate or at an interface between the IC structures 100-1-100-4 and the substrate 102. In the example illustrated in FIG. 1C, the plurality of conductive vias 108 pass or extend entirely through the IC structures 100-1-100-4 (e.g., entirely through the die or die stacks) so that portions of the conductive vias 108 are coplanar with top layers of the IC structures through which they pass. In the examples in which the insulator material 115 and/or a dummy die are over the IC structures, the plurality of conductive vias 108 extend through the insulator material 115 and/or through the dummy die 117. Although four IC structures 100-1-100-4 are illustrated in FIG. 1C, the assembly 160 may include fewer than or more than four coplanar IC structures bonded with the substrate 102.

The exposed ends of the conductive vias 108 at the side 131 may then be coupled with a circuit board (e.g., by flipping over and attaching the assembly 160 to a circuit board in accordance with any suitable technique). For example, FIG. 1D illustrates a cross-sectional view of the assembly 160 of FIG. 1C after flipping over the assembly and attaching the assembly 160 to the circuit board 101. As can be seen in FIG. 1D, the side 131 of the assembly 160 is bonded with the circuit board 101 via an interface layer including conductive bumps 114. Conductive interconnects in various ones of the IC structures 100-1, 100-2, 100-3, and 100-4 may be coupled with one another with a path that may include the conductive vias 108 in those IC structures and conductive interconnects in the substrate 102 and/or conductive interconnects in the circuit board 101.

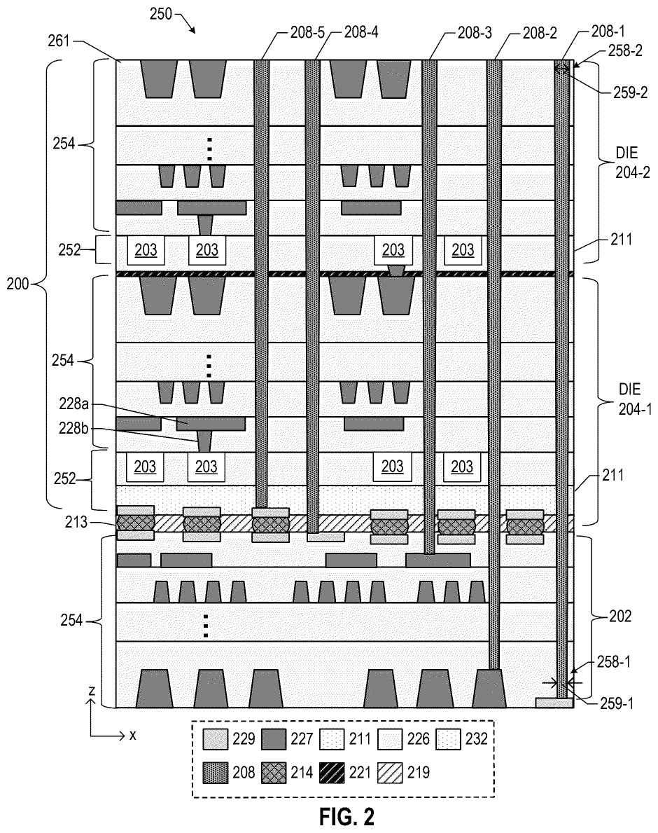

FIG. 2 illustrates a cross-sectional view of an assembly 250 with conductive vias for 3D integration. In the example illustrated in FIG. 2, the assembly 250 includes an IC structure 200 that includes two stacked dies 204-1, 204-2 over a substrate 202. The first die 204-1 and the second die 204-2 each include FEOL layers 252 and BEOL layers 254. The FEOL layers 252 include a device region 211, and may also include a substrate 232 over which the device region 211 is disposed. The device region 211 includes devices (of which devices 203 are shown). The substrate 232 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline.

The device 203 is an example of a frontend device. The device 203 may be considered a “frontend device” due to its location in a FEOL layer. According to examples, the device 203 may include a transistor of any architecture, such as any non-planar or planar architecture. Non-planar transistors such as double-gate transistors, tri-gate transistors, FinFETs, and nanowire/nanoribbon/nanosheet transistors refer to transistors having a non-planar architecture. In comparison to a planar architecture where the transistor channel has only one confinement surface, a non-planar architecture is any type of architecture where the transistor channel has more than one confinement surface. A confinement surface refers to a particular orientation of the channel surface that is confined by the gate field. Devices in the device region 211 may be electrically isolated from one another by any suitable insulator material 226.

The BEOL layers 254 may include a plurality of conductive interconnects 227 electrically coupled to (e.g., in electrically conductive contact with at least portions of) one or more of the plurality of devices of the FEOL layers 252. Various BEOL interconnect layers 254 may be/include one or more metal layers of a metallization stack of the die 204-1. In the example illustrated in FIG. 2, the interconnect layers 254 are disposed over a front side of the device region, and therefore may be considered frontside interconnect layers. In other examples, one or both of the dies 204-1 and 204-2 may include both frontside and backside interconnect layers. The die 204-1 may also include one or more backend devices (not shown). A device may be considered a “backend device” due to its location in a BEOL layer. A backend device may be present in lower or higher up interconnect layers in the metallization stack. In one example, a backend device may include a transistor of any architecture, such as any non-planar or planar architecture, or other device.

Various metal layers of the BEOL interconnect layers 254 may be used to interconnect the various inputs and outputs of the devices (e.g., logic devices) in the FEOL layer 252. In one example, each of the BEOL interconnect layers 254 may include vias and lines/trenches. For example, the BEOL interconnect layers 254 include via portions 228b and line or trench/interconnect portions 228a. The trench portion 228a of a metal layer is configured for transferring signals and power along electrically conductive (e.g., metal) lines (also sometimes referred to as “trenches”) extending in the x-y plane (e.g., in the x or y directions), while the via portion 228b of a metal layer is configured for transferring signals and power through electrically conductive vias extending in the z-direction, e.g., to any of the adjacent metal layers above or below. Accordingly, in one example, vias connect metal structures (e.g., metal lines or vias) from one metal layer to metal structures of an adjacent metal layer. While referred to as “metal” layers, various layers of the BEOL interconnect layers 254 may include only certain patterns of conductive metals, e.g., copper (Cu), aluminum (Al), tungsten (W), or cobalt (Co), or metal alloys, or more generally, patterns of an electrically conductive material, formed in an insulating medium such as an interlayer dielectric (ILD) material 226. The insulating medium may include any suitable ILD materials such as silicon oxide, carbon-doped silicon oxide, silicon carbide, silicon nitride, aluminum oxide, and/or silicon oxynitride. In some embodiments, the dielectric material 226 disposed between the interconnect structures in different ones of the interconnect layers and disposed in the device region 211 may have different compositions; in other embodiments, the composition of the dielectric material 226 between different interconnect layers and/or in the device region 211 may be the same. The example illustrated in FIG. 2 depicts three interconnect layers, however, fewer or more interconnect layers may be present.

The second die 204-2 is stacked over and bonded with the first die 204-1 via an interface 221. Although FIG. 2 depicts the second die 204-2 as having the same width (e.g., the same dimension along the x-axis as shown in FIG. 2), the second die 204-2 may have a width that is different from the first die 204-1. In some examples, one or multiple smaller coplanar dies may be bonded over the first die 204-1. The interface 221 between the first die 204-1 and the second die 204-2 may include, for example, a hybrid bonding interface, such as the hybrid bonding interface 121 discussed above with respect to FIG. 1C. In other examples, the interface 221 may include conductive bumps.

The die stack that includes the dies 204-1 and 204-2 is over and bonded with the substrate 202 via an interface 213. The substrate 202 may be an example of the substrate 102, discussed above, and may be referred to as an IC structure, an interconnect structure, a support structure, an interposer. The interface 213 includes conductive bumps 214 between the IC structure 200 and the substrate 202 (e.g., between the die 204-1 and the substrate 202) and an insulator material 219 in a plane with the conductive bumps (e.g., in a plane substantially parallel with the substrate 202 and the x-y plane as shown in FIG. 2, where the y-axis is going into and coming out of the page). The interface 213 may also be referred to as an interface layer including the conductive bumps 214. The conductive bumps 214 may be an example of the conductive bumps 114 discussed above. In the example illustrated in FIG. 2, a conductive bump is between and coupled with conductive elements in the two bonded IC structures. For example, the conductive bumps shown in FIG. 2 are either between two conductive pads 229, or between a conductive pad 229 and a conductive via 208. Although only a single die stack (e.g., the IC structure 200) is shown as bonded over the substrate 202, more than one IC structure may be bonded over the substrate, such as shown in FIG. 1C. The substrate 202 may include a plurality of interconnect layers 254 that include conductive interconnects 227.

The assembly 250 also includes a plurality of conductive vias 208 that extend through the IC structure 200 (e.g., completely through the dies 204-1, 204-2) and couple with a conductive element of the substrate 202. In the example shown in FIG. 2, the conductive vias 208-1, 208-2, 208-3, 208-4, and 208-5 extend entirely through the IC structure 200, so that portions of the conductive vias 208-1, 208-2, 208-3, 208-4, and 208-5 are coplanar with the bottom and top layers or faces of the IC structure 200. For example, the conductive vias 208-1, 208-2, 208-3, 208-4, and 208-5 are in a same plane as a top metal layer of the die 204-2. Thus, in one example, the conductive vias 208-1, 208-2, 208-3, 208-4, and 208-5 extend between a metal layer of the IC structure 200 and the substrate 202 (e.g., between a furthest metal layer 261 of the IC structure 200 from the substrate 202 and a metal layer of the substrate), where a portions of the conductive vias 208-1, 208-2, 208-3, 208-4, and 208-5 are coplanar with conductive interconnects of the metal layer of the IC structure 200. For example, the end 258-2 of the conductive via 208-1 is coplanar with the metal layer 261 and with conductive interconnects of the metal layer 261. In the example illustrated in FIG. 2, the 208-1, 208-2, 208-3, 208-4, and 208-5 also extend through both the metal layers (e.g., metallization stacks) and the device regions 211 of the dies 204-1 and 204-2, as well as through the interface 221 between the dies 204-1, 204-2 of the IC structure 200. In an example in which one or both of the dies 204-1, 204-2 include both frontside and backside metal layers, one or more of the conductive vias 208-1, 208-2, 208-3, 208-4, and 208-5 may extend through both the frontside and backside metal layers of a die.

The conductive vias 208-1-208-5 have different lengths (where the length is a dimension of the conductive vias 208-1-208-5 in a plane substantially orthogonal to the substrate 202, along the z-axis) and land or terminate at different points in the IC structure 200 or the substrate 202. Some of the conductive vias 208-1-208-5 shown in FIG. 2 (e.g., the conductive vias 208-1, 208-2, 208-3, and 208-4) extend through the interface 213 (e.g., through the insulator material 219 that is coplanar with the conductive bumps 214). In some examples, one or more of the conductive vias 208-1-208-5 may extend between adjacent conductive bumps 214 so that a portion of the conductive vias is between the adjacent conductive bumps 214 and in a same plane with the conductive bumps 214. In other examples, one or more conductive vias 208-1-208-5 may extend through the interface 213 at the periphery of the interface 213, so that the conductive via is not between adjacent bumps. In one such example, the conductive via may still be adjacent to or neighboring at least one conductive bump 214.

In the example illustrated in FIG. 2, the conductive vias 208-1-208-4 that extend through the interface 213 terminate or land on a conductive element in the substrate 202. For example, the conductive via 208-1 is coupled with a bonding pad 229. The conductive vias 208-2, 208-3 are coupled with conductive lines (e.g., trench portions 228a) in different metal layers. The conductive via 208-4 is coupled with a conductive pad at the interface 213 (e.g., a conductive pad that is coplanar with a face of the substrate 202 that is bonded with the IC structure 200, and coplanar with the other conductive pads of the substrate 202 that are coupled with the conductive bumps 214). The conductive via 208-5 does not extend through the interface 213, but is coupled with a conductive element of the IC structure 200. As shown in FIG. 2, the conductive via 208-5 is coupled with a conductive pad 229; however, in other examples, the conductive via 208-5 may be coupled directly with the conductive bump 214 or another conductive element of the IC structure 200.

As mentioned above, the conductive vias 208 may be formed in the assembly 250 after bonding the IC structure 200 with the substrate 202 from a top face or side of the IC structure 200 (e.g., the conductive vias 208 may be formed from the side or face of the IC structure 200 opposite the side or face that is bonded with the substrate 202). Therefore, in the example illustrated in FIG. 2, the conductive vias 208 taper towards the substrate 202. For example, the conductive via 208-1 has a first end 258-1 coupled with a conductive element (e.g., a conductive pad 229), and a second end 258-2 that is opposite the first end 258-1. The first end 258-1 has a first width 259-1 and the second end 258-2 has a second width 259-2 that is larger than the first width 259-1 (where the first width 259-1 and the second width 259-2 are dimensions of the conductive via 208-1 in a plane substantially parallel to the substrate 202). In other words, the first end 258-1 of the conductive via 208-1 that is coupled with the conductive element of substrate 202 is narrower than the second end 258-2 of the conductive via 208-1 that is opposite from the first end 258-1. After flipping over the assembly 250 and attaching the assembly to a circuit board, the second end 258-2 (e.g., the wider end) of the conductive via 208-1 is closer to the circuit board than the first end 258-1.

Thus, the substrate 202 is an IC structure including metal layers, the IC structure 200 includes metal layers and devices 203, and one or more conductive vias 208 extend between a metal layer of the substrate 202 and a metal layer of the IC structure 200. Although FIG. 2 depicts only two dies 204-1 and 204-2 over and bonded with the substrate 202, in other examples, fewer dies (i.e., a single die) or more than two dies (e.g., three dies, four dies, etc.) may be stacked over and bonded with the substrate 202. In some examples, the conductive interconnects of the substrate 202 couple with the conductive vias 208 though the dies 204-1, 204-2 and/or with conductive vias through other dies or die stacks bonded with the substrate 202.

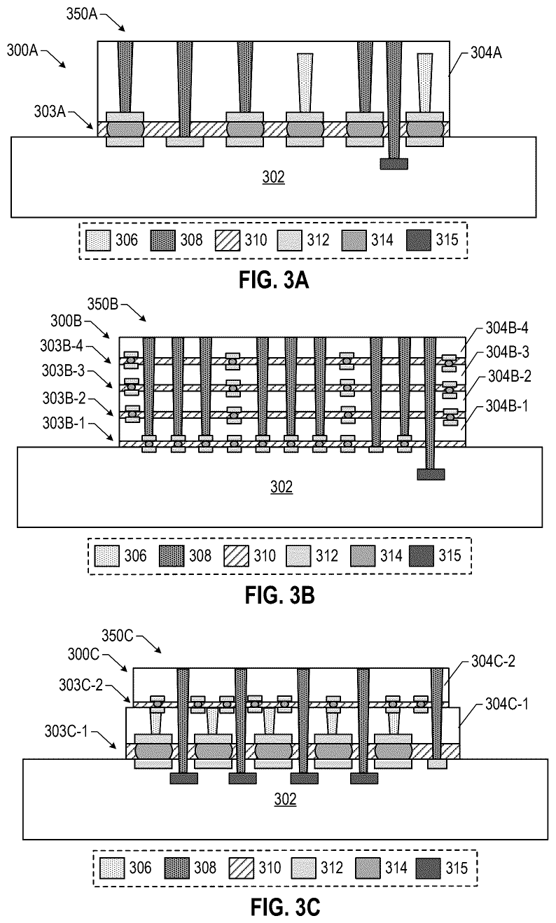

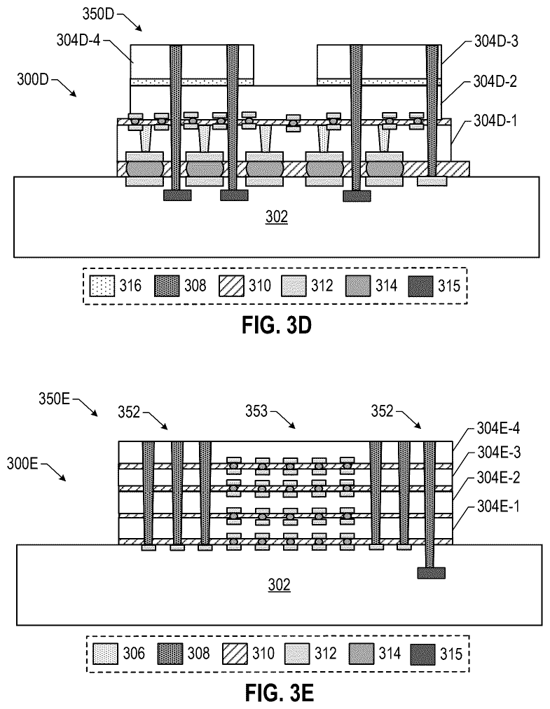

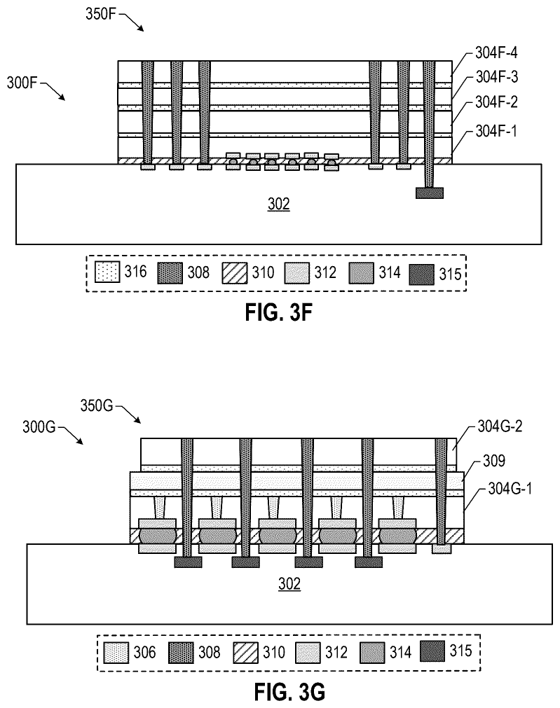

FIGS. 3A-3G illustrate cross-sectional views of examples of assemblies in which conductive vias for 3D integration may be formed. Turning first to FIG. 3A, the illustrated assembly 350A includes an IC structure 300A, which includes a single die 304A that is over and bonded with a substrate 302. The substrate 302 may be an example of the substrates 102 and 202 discussed above. The die 304A may be an example of the dies 104 and 204 discussed above. For example, the die 304A may include compute logic, memory devices, or both compute logic and memory devices. In the example illustrated in FIG. 3A, the die 304A is bonded with the substrate 302 via an interface 303A. The interface 303A includes a plurality of conductive bumps 314 and an insulator material 310 that is in a same layer as the conductive bumps 314 between the die 304A and the substrate 302. The conductive bumps 314 are coupled with conductive pads 312 in the die 304A and the substrate 302 on either side of the conductive bumps 314. The conductive bumps 314, the insulator material 310, and the conductive pads 312 may be examples of the conductive bumps 114 or 214, the insulator material 219, and the conductive pads 128 or 229, respectively.

The assembly depicted in FIG. 3A includes conductive vias 306 that extend between conductive elements within the die 304A (e.g., the conductive vias 306 start and end within the die 304A). In one example, the conductive vias 306 were formed in the die 304A (e.g., between a metal layer of the die 304A and pads 312 of the die 304A) prior to attaching the die 304A to the substrate 302. The assembly of FIG. 3A also includes conductive vias 308 that extend through the die 304A, at least one of which extends through the interface 303A between the die 304A and the substrate 302. The conductive vias 308 that extend through the interface 303A may couple with a bonding pad 312 of the substrate 302 at the interface 303A, a bonding pad 315 in another metal layer of the substrate 302, or with another conductive element of the substrate 302 (e.g., a metal line or other conductive element). Thus, in some examples, one or more conductive vias 308 may extend entirely through the die 304A and into the substrate 302.

FIG. 3B illustrates another assembly 350B including an IC structure 300B over and bonded with the substrate 302, where the IC structure 300B includes a die stack including a plurality of dies 304B-1, 304B-2, 304B-3, and 304B-4 stacked over one another. In the example illustrated in FIG. 3B, the dies are bonded with one another and with the substrate via interfaces that include conductive bumps 314 (e.g., via the interfaces 303B-1, 303B-2, 303B-3 and 303B-4). Thus, the conductive vias 308 extend through multiple interfaces 303B-1, 303B-2, 303B-3 and 303B-4 that include conductive bumps.

FIG. 3C illustrates another assembly 350C including an IC structure 300C that includes a stack of two dies 304C-1 and 304C-2. In the example in FIG. 3C, the top die 304C-2 is smaller than the die 304C-1 over which it is stacked (e.g., the die 304C-2 has a smaller area in a plane parallel with the substrate 302 than the die 304C-1). The interface 304C-1 between the IC structure 300C and the substrate 302 includes a first plurality of conductive bumps 314 with a first pitch and first width, and the interface 303C-2 between the dies 304C-1, 304C-2 includes a second plurality of conductive bumps 314 with a second pitch and a second width, which are different from the first pitch and first width (e.g., the conductive bumps 314 at the interface 303C-2 between the two dies 304C-1, 304C-2 are smaller and have a tighter pitch than the conductive bumps 314 at the interface 303C-1 between the IC structure 300C and the substrate 302. Thus, the conductive vias 308 extend through two different interfaces 303C-1, 303C-2 that include conductive bumps with different pitches. Therefore, there may be more conductive bumps 314 between adjacent conductive vias 308 at the interface 303C-2 than at the interface 303C-1.

FIG. 3D illustrates another assembly 350D including an IC structure 300D that includes a die stack in which two smaller dies (the dies 304D-3 and 304D-4) are stacked over the dies 304D-2 and 304D-1. In the example illustrated in FIG. 3D, the IC structure 300D (and therefore the bottom die 304D-1) is over and bonded with the substrate via an interface with conductive bumps 314. The die 304D-2 is over and bonded with the die 304D-1 via an interface with conductive bumps 314. The coplanar dies 304D3 and 304D-4 are over and bonded with the die 304D-2 via hybrid bonding interfaces 316. Therefore, the conductive vias 308 extend through multiple interfaces including bumps as well as a hybrid bonding interface.

FIG. 3E illustrates another assembly 350E including an IC structure 300E that is over and bonded with the substrate 302, where the IC structure 300E includes a die stack including a plurality of dies 304E-1, 304E-2, 304E-3, and 304E-4 stacked over one another. The IC structure 300E is similar to the IC structure 300B of FIG. 3B in that the dies are bonded with one another and with the substrate via interfaces that include conductive bumps 314, and the conductive vias 308 extend through multiple interfaces that include conductive bumps. However, the IC structure 300E differs from the IC structure 300B in that the conductive vias 308 that extend through the die stack at the edges or periphery 352 of the die stack rather than being distributed throughout the die stack in a plane substantially parallel with the substrate 302. In one such example, the IC structure 300E may include a stack of memory dies and a plurality of conductive vias in a central region 353 of the die stack (not shown in FIG. 3E). In one such example, the conductive vias may have been formed prior to bonding the IC structure 300E to the substrate 302, and may represent signal lines for transmitting data signals to and from the memory dies. In such an example, the conductive vias 308 that are formed after bonding the IC structure 300E to the substrate 302 and which extend through the die stack may be formed on the periphery (e.g., to avoid the central region 353 with the high density of data interconnects).

FIG. 3F illustrates another assembly 350F including an IC structure 300F that is over and bonded with the substrate 302, where the IC structure 300F includes a die stack including a plurality of dies 304F-1, 304F-2, 304F-3, and 304F-4 stacked over one another. The IC structure 300F is similar to the IC structure 300E of FIG. 3E, except that the dies 304F-1, 304F-2, 304F-3, and 304F-4 are bonded with one another via hybrid bonding interfaces 316 rather than interfaces with conductive bumps 314. Thus, the conductive vias 308 extend through multiple hybrid bonding interfaces 316.

FIG. 3G illustrates another assembly 350G including an IC structure 300G over and bonded with the substrate 302. The IC structure 300G includes a die stack of two dies 304G-1 and 304G-2, and an interconnect die 309 between the dies 304G-1 and 304G-2. One face or side of the interconnect die 309 is hybrid-bonded with the die 304G-1 and the opposite face or side of the interconnect die 309 is bonded with the die 304G-2.

Thus, FIGS. 3A-3G illustrate some examples of IC structures that may be bonded over a substrate. Any or all of the IC structures 300A-300G may be bonded over the same substrate and attached to the same circuit board. Other examples of IC structures that include at least one die may be bonded over the substrate to form an assembly in which a conductive via for 3D integration may be formed.

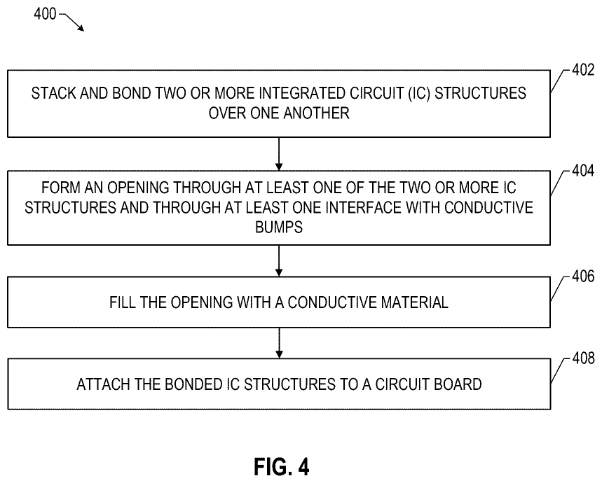

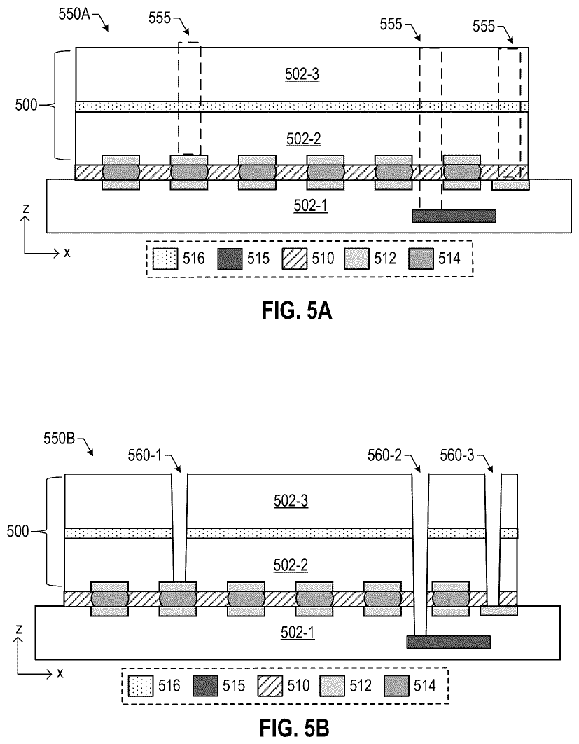

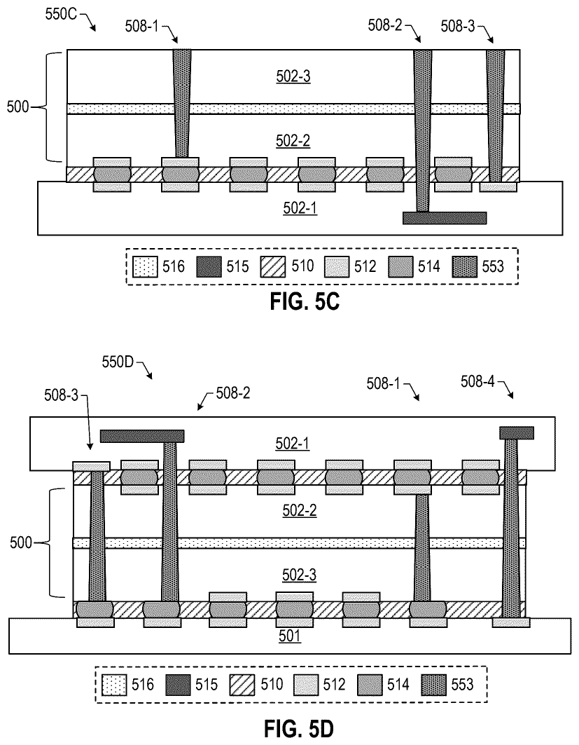

FIG. 4 is a flow diagram of an example method 400 for fabricating a microelectronic assembly with conductive vias for 3D integration. FIGS. 5A-5D provide different views at various stages in the fabrication of an example assembly according to the method of FIG. 4, in accordance with some embodiments. Although the operations of the method of FIG. 4 are illustrated once each and in a particular order, the operations may be performed in any suitable order and repeated as desired. For example, one or more operations may be performed in parallel to fabricate multiple microelectronic assemblies with conductive vias for 3D integration substantially simultaneously. In another example, the operations may be performed in a different order to reflect the structure of a microelectronic assembly in which conductive vias for 3D integration will be implemented.

In addition, the example fabricating methods of FIG. 4 may include other operations not specifically shown in FIG. 4, such as various cleaning or planarization operations as known in the art. For example, in some embodiments, a support, as well as layers of various other materials subsequently deposited thereon, may be cleaned prior to, after, or during any of the processes of the methods described herein, e.g., to remove oxides, surface-bound organic and metallic contaminants, as well as subsurface contamination. In some embodiments, cleaning may be carried out using e.g., chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the intermediate IC structures described herein may be planarized prior to, after, or during any of the processes of the method of FIG. 4 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

Turning to FIG. 4, the method 400 begins with a process 402 of stacking and bonding two or more IC structures over one another. The assembly 550A of FIG. 5A is an example resulting assembly of the process 402. The assembly 550A includes a first IC structure 502-1, a second IC structure 502-2 stacked over and bonded with the first IC structure 502-1, and a third IC structure 502-3 stacked over and bonded with the second IC structure 502-2. The IC structure 502-1 may be an example of the substrates 102 or 202, discussed above, and may include conductive elements, such as the conductive pads 512 and/or conductive interconnects 515, such as shown in FIG. 5A. The IC structures 502-2, 502-3 may be two dies that make up one IC structure 500 (e.g., a die stack) bonded with the IC structure 502-1. In one such example, the IC structures 502-2 and 502-3 are fabricated and bonded together via a hybrid bonding process, resulting in the IC structure 500 that includes a hybrid bonding interface 516 between the two IC structures 502-2, 502-3. In other examples, the two IC structures 502-2 and 502-3 may be bonded together with another suitable technique. Each of the IC structures 502-2 and 502-3 may have placeholder regions 555 that are reserved for forming conductive vias during or after assembly. Placeholder regions 555 may include regions that lack other devices or interconnects to accommodate the subsequent formation of conductive vias in those regions.

The combined IC structure 500 may then be bonded to the IC structure 502-1. In the example shown in FIG. 5A, the IC structure 500 is bonded with the IC structure 502-1 with a plurality of conductive bumps 514, which are between conductive pads of the IC structures 500 and 502-1. An insulator material 510 may also be present between the IC structures 500 and 502-1 in a plane with the plurality of conductive bumps 514. In some examples, multiple other IC structures may be bonded over the IC structure 502-1, such as shown in FIG. 1C. Thus, multiple IC structures from different fabs may be bonded with the IC structure 502-1 to form an assembly 550A.

The method 400 continues with a process 404 of forming an opening through at least one of the two or more IC structures and through at least one interface with conductive bumps. The assembly 550B of FIG. 5B is an example resulting assembly of the process 404. The assembly 550B includes openings 560-1, 560-2, and 560-3 through the IC structure 500. Forming the openings 560-1, 560-2, and 560-3 may involve any suitable masking and etching techniques that enable etching through multiple layers of different materials. For example, the process 404 of forming the openings 560-1, 560-2, and 560-3 involves etching through multiple layers of semiconductor material, insulator material, and may also involve etching through conductive material. Any suitable etching technique, e.g., a dry etch, such as e.g., radio frequency (RF) reactive ion etch (RIE) or inductively coupled plasma (ICP) RIE may be used to form the openings 560-1, 560-2, and 560-3.

The method 400 continues with a process 406 of filling the opening with a conductive material. The assembly 550C of FIG. 5C is an example resulting assembly of the process 406. The assembly 550C includes conductive vias 508-1, 508-2, and 508-3 formed by filling the openings 560-1, 560-2, and 560-3 with a conductive material 553. The electrically conductive material 553 may include any suitable electrically conductive material, such as any of those described above with respect to FIG. 1A, and may be deposited in the process 406 using a technique such as atomic layer deposition (ALD), chemical vapor deposition (CVD), plasma enhanced CVD (PECVD), or/and physical vapor deposition (PVD) processes such as sputter. Although not shown in FIG. 5C, a liner may be provided in the openings 560-1, 560-2, and 560-3 prior to filling the openings 560-1, 560-2, and 560-3 with the conductive material 553.

The method 400 continues with a process 408 of attaching the bonded IC structures to a circuit board. The assembly 550D of FIG. 5D is an example resulting assembly of the process 408. The assembly 550D includes a circuit board 501 over which the preliminary assembly (e.g., the assembly 550C including the bonded IC structures 502-1, 502-2, and 502-3) is bonded. The circuit board 501 may be an example of the circuit board 101, discussed above. As can be seen in FIG. 5D, the assembly 550C was first flipped over prior to bonding to the circuit board to enable the exposed tops of the conductive vias to be bonded with conductive elements of the circuit board 501. Therefore, the conductive vias 508-1, 508-2, and 508-3 taper away from the circuit board 501 and towards the conductive elements of the IC structure 502-1 with which they are coupled.

In the example illustrated in FIG. 5D, an additional conductive via 508-4 was formed after providing the insulator material 510 over the IC structure 500, but prior to flipping over and bonding the assembly to the circuit board 501. Therefore, the conductive via 508-4 extends through the IC structure 500 and also through the insulator material 510 of the interface between the IC structure 500 and the circuit board circuit board 501. Although only a single IC structure 500 is shown as disposed between and bonded with the IC structure 502-1 and the circuit board 501, multiple different IC structures may be bonded with the IC structure 502-1 to form a preliminary assembly in which conductive vias may be formed. In one such example, the assembly with multiple IC structures and conductive vias may be flipped over and attached to the circuit board 501. For example, FIG. 1D illustrates an assembly with multiple different IC structures between a substrate 102 and a circuit board 101.

Thus, FIG. 4 illustrates a method 400 for fabricating a microelectronic assembly with conductive vias for 3D integration. Performing the method 400 may result in several features in the final assembly that are characteristic of the use of the method 400. For example, one such feature is illustrated in the assembly shown in FIG. 5D, in which an IC structure 500 that includes one or more dies stacked over one another is between and bonded with a circuit board 501 and an IC structure 502-1, such as a substrate. One or more conductive vias 508-1-508-4 extend through the IC structure 500 and couple with conductive elements in the IC structure 502-1. The conductive vias 508-1-508-4 taper in a direction away from the circuit board 501 and towards the substrate (e.g., portions of the conductive vias 508-1-508-4 that are proximate to the circuit board 501 are wider than portions of the conductive vias 508-1-508-4 that are further from the circuit board 501 (and closer to the IC structure 502-1). In some examples, one or more of the conductive vias 508-1-508-4 extend through one or more interfaces that include conductive bumps 514.

IC devices, structures, and assemblies including conductive vias for 3D integration as described herein (e.g., as described with reference to FIGS. 1A-1D, 2, 3A-3G, 4, and 5A-5D) may be used to implement any suitable components. For example, in various embodiments, IC devices described herein may be part of one or more of: a central processing unit, a memory device (e.g., a high-bandwidth memory device), a memory cell, a logic circuit, input/output circuitry, a field programmable gate array (FPGA) component such as an FPGA transceiver or an FPGA logic, a power delivery circuitry, an amplifier (e.g., a III-V amplifier), Peripheral Component Interconnect Express (PCIE) circuitry, Double Data Rate (DDR) transfer circuitry, a computing device (e.g., a wearable or a handheld computing device), a system including one or more of the aforementioned devices, etc.

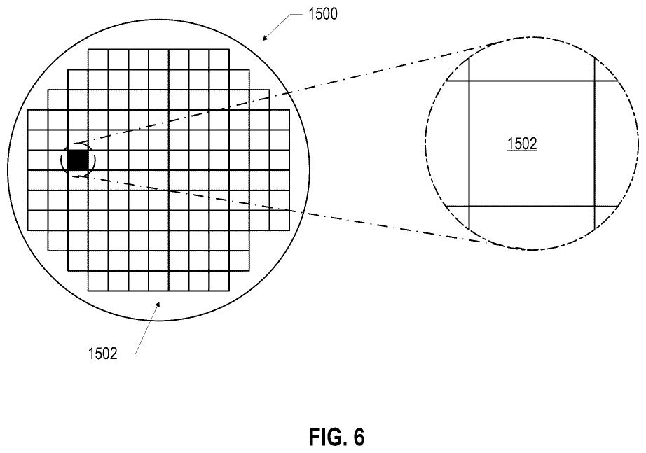

The devices, structures, and assemblies disclosed herein, e.g., the assemblies 150, 160, 250, 350A, 350B, 350C, 350D, 350E, 350F, 350G, 550D or any variations thereof, may be included in any suitable electronic component. FIGS. 6-9 illustrate various examples of apparatuses that may include any of the IC structures or assemblies disclosed herein.

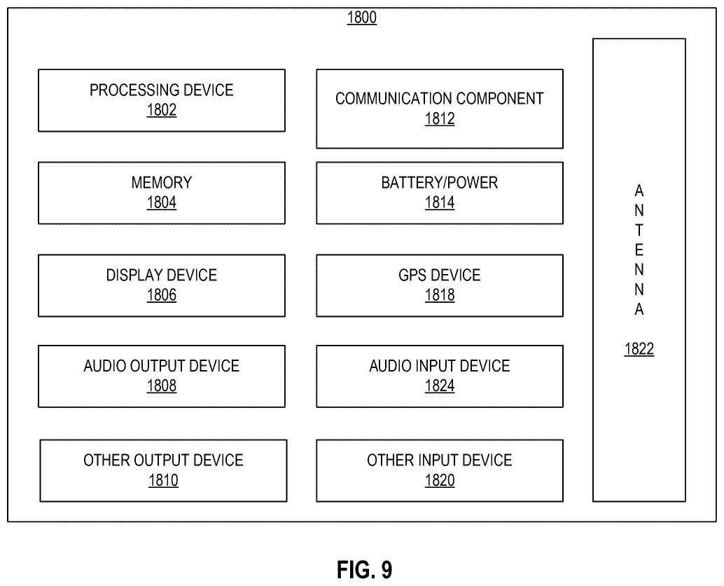

FIG. 6 is a top view of a wafer 1500 and dies 1502 that may include one or more IC structures in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more IC structures as described herein (e.g., any of the structures and/or dies 102, 104, 202, 204-1, 204-2, 304A, 304B-1-304B-4, 304C-1, 304C-2, 304D-1-304D-3, 304E-1-304E-4, 304F-1-304F-4, 304G-1, 304G-2, 502-1, 502-2, 502-3, or any variations thereof described herein, or any combination of such IC structures), one or more transistors and/or supporting circuitry to route electrical signals to the transistors, as well as any other IC components. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 9) or other logic that is configured to store information in the memory devices or execute instructions stored in the memory array.

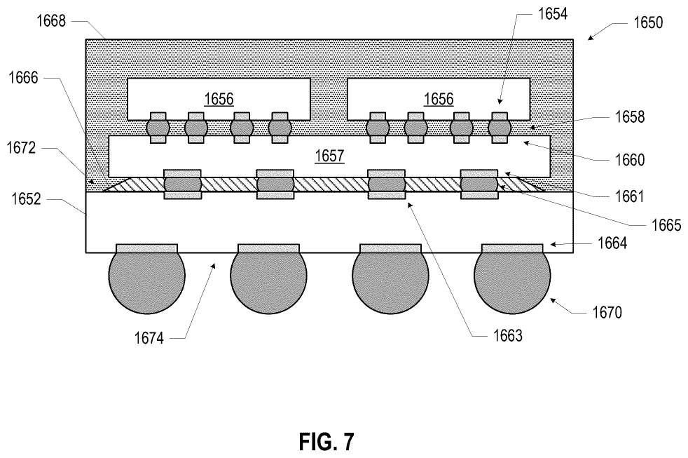

FIG. 7 is a side, cross-sectional view of an example IC package 1650 that may include one or more IC structures in accordance with any of the embodiments disclosed herein (e.g., any of the assemblies 150, 160, 250, 350A, 350B, 350C, 350D, 350E, 350F, 350G, 550D, or any variations thereof described herein, or any combination). In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 7 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 7 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

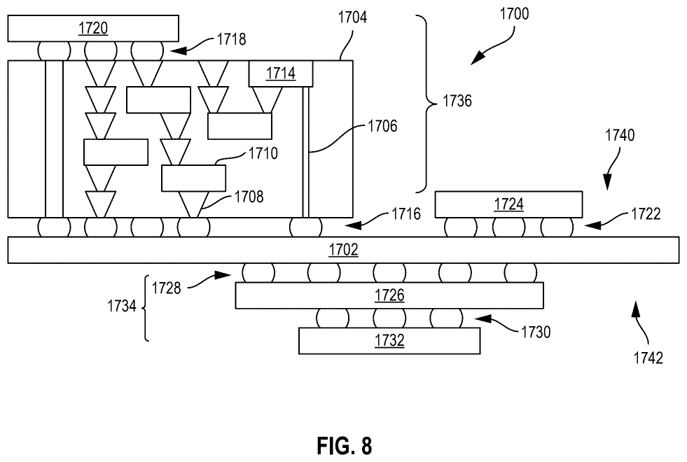

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 7 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 8.

The dies 1656 may take the form of any of the embodiments of the die 1502 discussed herein. In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high-bandwidth memory).

Although the IC package 1650 illustrated in FIG. 7 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 7, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 8 is a side, cross-sectional view of an IC device assembly 1700 that may include one or more IC packages or other electronic components (e.g., a die) including one or more IC devices in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 7 (e.g., may include one or more of assemblies 150, 160, 250, 350A, 350B, 350C, 350D, 350E, 350F, 350G, 550D, or any variations thereof described herein, or any combination of such structures).

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 8 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 8), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 8, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 6), an IC device, an assembly (e.g., one or more of assemblies 150, 160, 250, 350A, 350B, 350C, 350D, 350E, 350F, 350G, 550D, or any variations thereof described herein, or any combination of such structures), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 8, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 8 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 9 is a block diagram of an example electrical device 1800 that may include one or more IC structures 100 in accordance with any of the embodiments disclosed herein. For example, any suitable ones of the components of the electrical device 1800 may include one or more of the IC device assemblies 1700, IC packages 1650, or dies 1502 disclosed herein. A number of components are illustrated in FIG. 9 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 9, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random-access memory (eDRAM) or spin transfer torque magnetic random-access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include another output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra-mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 provides a microelectronic assembly, including a first IC structure (e.g., a substrate) and a second IC structure stacked over and bonded with the first IC structure; an interface layer between the first IC structure and the second IC structure, where the interface layer includes a plurality of conductive bumps (e.g., in contact with the first IC structure and the second IC structure, and coupled with conductive elements in the first and second IC structures) and an insulator material in a plane with the plurality of conductive bumps, where the plane is substantially parallel to the first IC structure; and a conductive via through the interface layer and coupled with a conductive element of the first IC structure.

Example 2 provides the microelectronic assembly of example 1, where: the conductive via extends through the second IC structure, and a first portion of the conductive via is coupled with the conductive element of the first IC structure and is narrower than a second portion of the conductive via that is opposite from the first portion.

Example 3 provides the microelectronic assembly of example 2, where the conductive element is a first conductive element, and where the microelectronic assembly further includes a circuit board over which the first IC structure and the second IC structure are stacked, where the second portion of the conductive via is closer to the circuit board than the first portion.

Example 4 provides the microelectronic assembly of any one of examples 1-3, where: the first IC structure includes a first metal layer, the second IC structure includes a second metal layer, where the second metal layer is a furthest metal layer of the second IC structure from the first IC structure, the conductive via extends between the first metal layer and the second metal layer, and a portion of the conductive via is coplanar with a conductive interconnect of the second metal layer.

Example 5 provides the microelectronic assembly of any one of examples 1-4, where the plane is a first plane, the insulator material is a first insulator material, and where the microelectronic assembly further includes a third IC structure over the first IC structure and coplanar with the second IC structure (e.g., adjacent to the second IC structure), where: the third IC structure has a height that is greater than the second IC structure, and the height is a dimension of the third IC structure in a second plane substantially orthogonal to the first IC structure; and a second insulator material over the second IC structure in a third plane with the third IC structure (e.g., coplanar with the top face of the third IC structure), where the third plane is substantially parallel to the first IC structure.

Example 6 provides the microelectronic assembly of example 5, where: the conductive via extends through the second insulator material in the second plane.

Example 7 provides the microelectronic assembly of any one of examples 1-4, where the plane is a first plane, and where the microelectronic assembly further includes a third IC structure over the first IC structure and coplanar with the second IC structure, where: the third IC structure has a height that is greater than the second IC structure, and the height is a dimension of the third IC structure in a second plane substantially orthogonal to the first IC structure; and a dummy die (e.g., a die lacking active devices) over the second IC structure in a third plane with the third IC structure, where the third plane is substantially parallel to the first IC structure.

Example 8 provides the microelectronic assembly of any one of examples 1-7, where: the plurality of conductive bumps are coupled with respective conductive pads of the second IC structure, the conductive via is coupled with a further conductive pad of the second IC structure, and the further conductive pad is coplanar with the conductive pads.

Example 9 provides the microelectronic assembly of any one of examples 1-8, where: the conductive via extends completely through at least one of the first IC structure and the second IC structure (e.g., and couples with further bumps or another interface).

Example 10 provides the microelectronic assembly of any one of examples 1-9, where: the conductive via extends completely through the first IC structure and the second IC structure (e.g., and couples with further bumps and/or other interfaces).

Example 11 provides the microelectronic assembly of any one of examples 1-10, where: the second IC structure includes a logic die, and the first IC structure lacks transistors (e.g., the first IC structure may be an interposer or substrate that lacks compute logic).

Example 12 provides the microelectronic assembly of any one of examples 1-11, further including a third IC structure stacked over the first IC structure and the second IC structure and bonded with the second IC structure, where the conductive via extends through at least two of the first IC structure, the second IC structure, and the third IC structure.

Example 13 provides the microelectronic assembly of example 12, where the interface layer is a first interface layer, the plurality of conductive bumps is a first plurality of conductive bumps, and where the microelectronic assembly further includes a second interface layer between the third IC structure and the second IC structure, where the second interface layer includes a second plurality of conductive bumps, and where the conductive via extends through the second interface layer.

Example 14 provides the microelectronic assembly of example 13, where: the first plurality of conductive bumps has a first pitch, and the second plurality of conductive bumps has a second pitch that is different from the first pitch (e.g., smaller/tighter).

Example 15 provides the microelectronic assembly of any one of examples 12-14, where the interface layer is a first interface layer, and where the microelectronic assembly further includes a second interface layer between the third IC structure and the first or second IC structures, where the second interface layer includes a hybrid bonding interface.

Example 16 provides the microelectronic assembly of any one of examples 12-15, where the interface layer is a first interface layer, and where the microelectronic assembly further includes an interconnect die between and hybrid-bonded with the third IC structure and the first IC structure, where the conductive via extends through the interconnect die.

Example 17 provides a microelectronic assembly, including a substrate; a first IC structure over the substrate in a first plane that is substantially parallel to the substrate, where the first IC structure includes one or more first dies, and where the first IC structure has a first thickness; a second IC structure over the substrate in the first plane, where the second IC structure includes one or more second dies, and where the second IC structure has a second thickness that is smaller than the first thickness; a first insulator material over the second IC structure in a second plane with the first IC structure, where the second plane is substantially parallel to the substrate; a plurality of conductive bumps between the second IC structure and the substrate; a second insulator material between the second IC structure and the substrate and coplanar with the plurality of conductive bumps; and a conductive via through the first insulator material and through the second insulator material.

Example 18 provides the microelectronic assembly of example 17, further including a circuit board bonded with the first IC structure and the second IC structure, where the first IC structure and the second IC structure are between the circuit board and the substrate.

Example 19 provides a microelectronic assembly, including a circuit board; a first IC structure over and bonded with the circuit board, where the first IC structure includes one or more first dies stacked over one another; a second IC structure over and bonded with the circuit board, where the second IC structure includes one or more second dies stacked over one another; a substrate over and bonded with the first IC structure and the second IC structure; an interface layer including conductive bumps between the circuit board and the substrate; a first conductive via through the first IC structure and through the interface layer; a second conductive via through the second IC structure; and a conductive interconnect coupled with the first conductive via and the second conductive via.

Example 20 provides the microelectronic assembly of example 19, where: the interface layer is between two adjacent dies of the first IC structure.

Example 21 provides the microelectronic assembly of example 19, where: the interface layer is between the first IC structure and the substrate.

Example 22 provides the microelectronic assembly of any one of examples 19-21, where: the conductive interconnect is disposed in the substrate.

Example 23 provides the microelectronic assembly of any one of examples 19-21, where: the conductive interconnect is disposed in the circuit board.

Example 24 provides the microelectronic assembly according to any one of examples 1-23, where the microelectronic assembly includes or is a part of a central processing unit.

Example 25 provides the microelectronic assembly according to any one of examples 1-24, where the microelectronic assembly includes or is a part of a memory device.

Example 26 provides the microelectronic assembly according to any one of examples 1-25, where the microelectronic assembly includes or is a part of a logic circuit.

Example 27 provides the microelectronic assembly according to any one of examples 1-26, where the microelectronic assembly includes or is a part of input/output circuitry.

Example 28 provides the microelectronic assembly according to any one of examples 1-27, where the microelectronic assembly includes or is a part of a field programmable gate array transceiver.

Example 29 provides the microelectronic assembly according to any one of examples 1-28, where the microelectronic assembly includes or is a part of a field programmable gate array logic.

Example 30 provides the microelectronic assembly according to any one of examples 1-29, where the microelectronic assembly includes or is a part of a power delivery circuitry.

Example 31 provides an IC package that includes a microelectronic assembly according to any one of examples 1-30.

Example 32 provides the IC package according to example 31, further including a further IC component coupled to the microelectronic assembly.

Example 33 provides the IC package according to example 32, where the further IC component includes a package substrate.

Example 34 provides the IC package according to example 32, where the further IC component includes an interposer.

Example 35 provides the IC package according to example 32, where the further IC component includes a further assembly or die.

Example 36 provides a computing device that includes a carrier substrate and an assembly coupled to the carrier substrate, where the assembly is an assembly according to any one of examples 1-30, or the assembly is included in the IC package according to any one of examples 31-35.

Example 37 provides the computing device according to example 36, where the computing device is a wearable or handheld computing device.

Example 38 provides the computing device according to examples 36 or 37, where the computing device further includes one or more communication chips.

Example 39 provides the computing device according to any one of examples 36-38, where the computing device further includes an antenna.

Example 40 provides the computing device according to any one of examples 36-39, where the carrier substrate is a motherboard.

Example 41 provides a method of fabricating a microelectronic assembly, the method including providing a first IC structure; stacking a second IC structure over the first IC structure and bonding the second IC structure with the first IC structure; forming an opening through at least the first IC structure and through an interface with conductive bumps; filling the opening with a conductive material; and attaching the bonded first and second IC structures to a circuit board.

Example 42 provides the method of example 41, further including flipping over a stack including the first IC structure and the second IC structure, and bonding the stack to the circuit board.

Example 43 provides the method according to any one of examples 41-42, where the microelectronic assembly is a microelectronic assembly according to any one of the preceding examples.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. A microelectronic assembly, comprising:
a first integrated circuit (IC) structure and a second IC structure stacked over and bonded with the first IC structure;
an interface layer between the first IC structure and the second IC structure, wherein the interface layer comprises a plurality of conductive bumps and an insulator material in a plane with the plurality of conductive bumps, wherein the plane is substantially parallel to the first IC structure; and
a conductive via through the interface layer and coupled with a conductive element of the first IC structure.

2. The microelectronic assembly of claim 1, wherein:
the conductive via extends through the second IC structure, and
a first portion of the conductive via is coupled with the conductive element of the first IC structure and is narrower than a second portion of the conductive via that is opposite from the first portion.

3. The microelectronic assembly of claim 2, wherein the conductive element is a first conductive element, and wherein the microelectronic assembly further comprises:
a circuit board over which the first IC structure and the second IC structure are stacked, wherein the second portion of the conductive via is closer to the circuit board than the first portion.

4. The microelectronic assembly of claim 1, wherein:
the first IC structure comprises a first metal layer,
the second IC structure comprises a second metal layer, wherein the second metal layer is a furthest metal layer of the second IC structure from the first IC structure,
the conductive via extends between the first metal layer and the second metal layer, and
a portion of the conductive via is coplanar with a conductive interconnect of the second metal layer.

5. The microelectronic assembly of claim 1, wherein the plane is a first plane, the insulator material is a first insulator material, and wherein the microelectronic assembly further comprises:
a third IC structure over the first IC structure and coplanar with the second IC structure, wherein:
the third IC structure has a height that is greater than the second IC structure, and
the height is a dimension of the third IC structure in a second plane substantially orthogonal to the first IC structure; and
a second insulator material over the second IC structure in a third plane with the third IC structure, wherein the third plane is substantially parallel to the first IC structure.

6. The microelectronic assembly of claim 5, wherein:
the conductive via extends through the second insulator material in the second plane.

7. The microelectronic assembly of claim 1, wherein the plane is a first plane, and wherein the microelectronic assembly further comprises:
a third IC structure over the first IC structure and coplanar with the second IC structure, wherein:
the third IC structure has a height that is greater than the second IC structure, and
the height is a dimension of the third IC structure in a second plane substantially orthogonal to the first IC structure; and
a dummy die over the second IC structure in a third plane with the third IC structure, wherein the third plane is substantially parallel to the first IC structure.

8. The microelectronic assembly of claim 1, wherein:
the plurality of conductive bumps are coupled with respective conductive pads of the second IC structure, the conductive via is coupled with a further conductive pad of the second IC structure, and
the further conductive pad is coplanar with the conductive pads.

9. The microelectronic assembly of claim 1, wherein:
the conductive via extends completely through at least one of the first IC structure and the second IC structure.

10. The microelectronic assembly of claim 1, wherein:
the conductive via extends completely through the first IC structure and the second IC structure.

11. The microelectronic assembly of claim 1, wherein:
the second IC structure comprises a logic die, and
the first IC structure lacks transistors.

12. The microelectronic assembly of claim 1, further comprising:
a third IC structure stacked over the first IC structure and the second IC structure and bonded with the second IC structure, wherein the conductive via extends through at least two of the first IC structure, the second IC structure, and the third IC structure.

13. The microelectronic assembly of claim 12, wherein the interface layer is a first interface layer, the plurality of conductive bumps is a first plurality of conductive bumps, and wherein the microelectronic assembly further comprises:
a second interface layer between the third IC structure and the second IC structure, wherein the second interface layer comprises a second plurality of conductive bumps, and wherein the conductive via extends through the second interface layer.

14. The microelectronic assembly of claim 13, wherein:
the first plurality of conductive bumps has a first pitch, and the second plurality of conductive bumps has a second pitch that is different from the first pitch.

15. The microelectronic assembly of claim 12, wherein the interface layer is a first interface layer, and wherein the microelectronic assembly further comprises:
a second interface layer between the third IC structure and the first or second IC structures, wherein the second interface layer comprises a hybrid bonding interface.

16. The microelectronic assembly of claim 12, wherein the interface layer is a first interface layer, and wherein the microelectronic assembly further comprises:
an interconnect die between and hybrid-bonded with the third IC structure and the first IC structure, wherein the conductive via extends through the interconnect die.

17. A microelectronic assembly, comprising:
a substrate;
a first integrated circuit (IC) structure over the substrate in a first plane that is substantially parallel to the substrate, wherein the first IC structure includes one or more first dies, and wherein the first IC structure has a first thickness;
a second IC structure over the substrate in the first plane, wherein the second IC structure includes one or more second dies, and wherein the second IC structure has a second thickness that is smaller than the first thickness;
a first insulator material over the second IC structure in a second plane with the first IC structure, wherein the second plane is substantially parallel to the substrate;
a plurality of conductive bumps between the second IC structure and the substrate;
a second insulator material between the second IC structure and the substrate and coplanar with the plurality of conductive bumps; and
a conductive via through the first insulator material and through the second insulator material.

18. The microelectronic assembly of claim 17, further comprising:
a circuit board bonded with the first IC structure and the second IC structure, wherein the first IC structure and the second IC structure are between the circuit board and the substrate.

19. A microelectronic assembly, comprising:
a circuit board;
a first integrated circuit (IC) structure over and bonded with the circuit board, wherein the first IC structure includes one or more first dies stacked over one another;
a second IC structure over and bonded with the circuit board, wherein the second IC structure includes one or more second dies stacked over one another;
a substrate over and bonded with the first IC structure and the second IC structure;
an interface layer comprising conductive bumps between the circuit board and the substrate;
a first conductive via through the first IC structure and through the interface layer;
a second conductive via through the second IC structure; and
a conductive interconnect coupled with the first conductive via and the second conductive via.

20. The microelectronic assembly of claim 19, wherein:
the interface layer is between two adjacent dies of the first IC structure.
